(19) United States
(12) Patent Application Publication
(10) Pub. No.: US 2010/0022057 A1
(43) Pub. Date: Jan. 28, 2010

(54) METHOD FOR FORMING A SEMICONDUCTOR DEVICE HAVING A FIN CHANNEL TRANSISTOR

(75) Inventors: Sung Woong Chung, Icheon-si (KR); Sang Don Lee, Guri-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/569,802

(22) Filed: Sep. 29, 2009

Related U.S. Application Data
(63) Continuation of application No. 11/529,355, filed on Sep. 29, 2006.

(30) Foreign Application Priority Data
Apr. 28, 2006 (KR) 10-2006-0038826

(51) Int. Cl. H01L 21/762; H01L 21/8242; H01L 21/28

(52) U.S. Cl. 438/239; 438/400; 438/592; 257/E21.545; 257/E21.646; 257/E21.19

(57) ABSTRACT

The semiconductor device includes a device isolation structure formed in a semiconductor substrate to define an active region having a recess region at a lower part of sidewalls thereof. The semiconductor device additionally has a fin channel region protruded over the device isolation structure in a longitudinal direction of a gate region; a gate insulating film formed over the semiconductor substrate including the protruded fin channel region; and a gate electrode formed over the gate insulating film to fill up the protruded fin channel region.

### CROSS-REFERENCES TO RELATED APPLICATIONS

The present application is a continuation of U.S. patent application Ser. No. 11/529,355, filed Sep. 29, 2006, which claims priority to Korean patent application number 10-2006-0038826, filed on Apr. 28, 2006, which are incorporated by reference in their entirety.

### BACKGROUND OF THE INVENTION

The present invention relates to a memory device. More particularly, the present invention relates to a semiconductor device having a fin channel transistor and a method for fabricating the same.

When a channel length of a cell transistor is decreased, ion concentration of a cell channel region is generally increased in order to maintain the threshold voltage of the cell transistor. An electric field in source/drain regions of the cell transistor is enhanced to increase leakage current. This results in degradation of the refresh characteristics of a DRAM structure. Therefore, there is a need for semiconductor devices in which the refresh characteristics are improved.

FIG. 1 is a simplified layout of a semiconductor device. The semiconductor device includes an active region 101 and a gate region 103. The active region is defined by a device isolation structure 130.

FIGS. 2a through 2c are simplified cross-sectional views illustrating a method for fabricating a semiconductor device, wherein FIGS. 2a through 2c are cross-sectional views taken along the line I-I′ of FIG. 1. A semiconductor substrate 210 having a pad insulating film (not shown) is etched using a device isolation mask (not shown) to form a trench (not shown) defining a fin-type active region 220. An insulating film for device isolation (not shown) is formed to fill the trench. The insulating film for device isolation is polished until the pad insulating film is exposed to form a device isolation structure 230. The pad insulating film is removed to expose the top surface of the fin-type active region 220.

Referring to FIG. 2b, a predetermined thickness of the device isolation structure 230 is etched using a recess gate mask (not shown) defining a gate region 103 shown in FIG. 1 to protrude an upper part of the fin-type active region 220 over the device isolation structure 230.

Referring to FIG. 2c, a gate insulating film 260 is formed over the protruded fin-type active region 220. A gate structure 295 is formed over the gate insulating film 260 of the gate region 103 shown in FIG. 1 to fill the protruded fin-type active region 220, wherein the gate structure 295 comprises a stacked structure of a gate electrode 265 and a gate hard mask layer pattern 290.

FIG. 3 is a simplified cross-sectional view illustrating a semiconductor device. If a voltage above the threshold voltage is applied to the gate, an inversion layer IL and a depletion region DR are formed in a semiconductor substrate under the gate insulating film 360.

According to the above conventional method for fabricating a semiconductor device, device characteristics such as the gate potential and ion concentration of a cell channel structure have to be adjusted in order to secure a desired Off-characteristic of the device, which causes increased leakage current from a storage node to the body of the semiconductor substrate. Accordingly, it is difficult to obtain proper refresh characteristics of the device due to the increased leakage current.

### BRIEF SUMMARY OF THE INVENTION

Embodiments of the present invention are directed to semiconductor devices having a fin channel transistor in an active region having a recess region at a lower part of sidewalls of the active region. According to one embodiment, the fin channel transistor has a fin channel region protruded over a device isolation structure and a gate structure that fills the fin channel region.

In one embodiment of the present invention, a semiconductor device comprises a device isolation structure formed in a semiconductor substrate to define an active region having a recess region at a lower part of sidewalls thereof. The semiconductor also includes a fin channel region protruded over the device isolation structure in a longitudinal direction of a gate region; a gate insulating film formed over the semiconductor substrate including the protruded fin channel region; and a gate electrode formed over the gate insulating film to fill up the protruded fin channel region.

According to another embodiment of the present invention, a method for fabricating a semiconductor device includes forming a device isolation structure in a semiconductor substrate to form an active region having a recess region at a lower part of sidewalls thereof; etching the device isolation structure by using a recess gate mask defining a gate region as an etching mask to form a fin channel region protruded over the device isolation structure; forming a gate insulating film over the exposed semiconductor substrate including the protruded fin channel region; and forming a gate structure including a stacked structure of a gate hard mask layer pattern and a gate electrode that fills up the protruded fin channel region over the gate insulating film corresponding to the gate region.

### BRIEF DESCRIPTION OF THE DRAWINGS

FIG. 1 is a simplified layout of a conventional semiconductor device.

FIGS. 2a through 2c are simplified cross-sectional views illustrating a conventional method for fabricating a semiconductor device.

FIG. 3 is a simplified cross-sectional view of a conventional semiconductor device.

FIG. 4 is a simplified layout of a semiconductor device according to one embodiment of the present invention.

FIGS. 5 and 6 are simplified cross-sectional views of a semiconductor device according to one embodiment of the present invention.

FIGS. 7a through 7e are simplified cross-sectional views illustrating a method for fabricating a semiconductor device according to one embodiment of the present invention.

FIGS. 8a through 8d are simplified cross-sectional views illustrating a method for fabricating a semiconductor device according to another embodiment of the present invention.

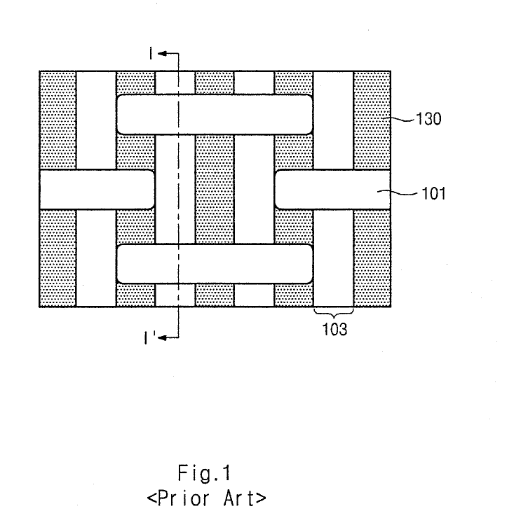

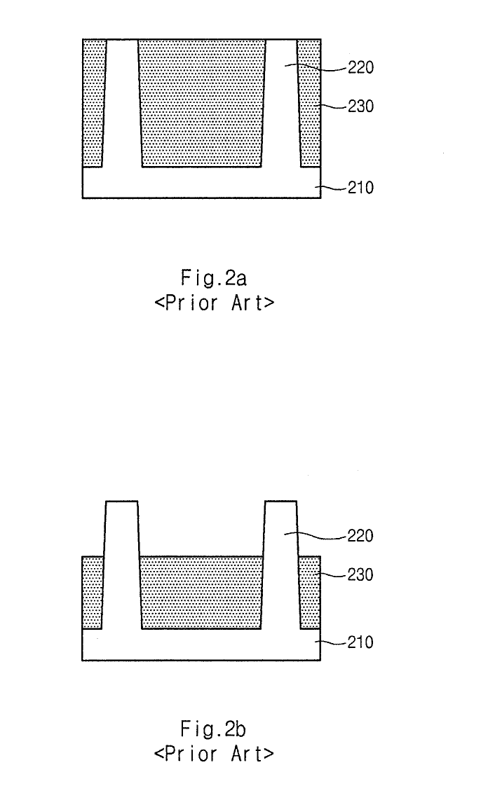

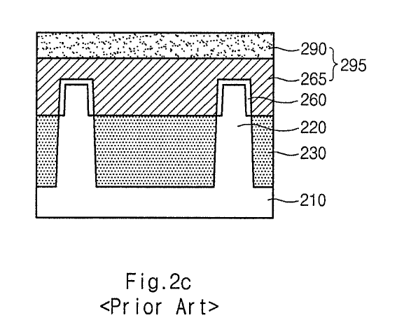

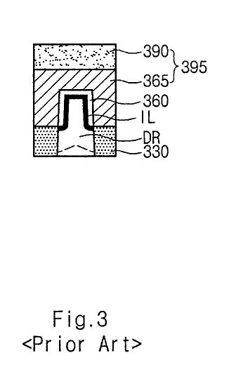

### DESCRIPTION OF SPECIFIC EMBODIMENTS

The present invention relates to semiconductor devices having a fin channel transistor in an active region having a recess region at a lower part of sidewalls of the active region. The fin channel transistor has a fin channel region protruded over a device isolation structure and a gate structure that fills the fin channel region. Accordingly, the fin channel transistor provides significantly improved refresh characteristic due to preventing leakage current flowing from storage nodes to body of the semiconductor substrate and improvement of the short channel effect (“SCE”) because of charges in the limited depletion region.

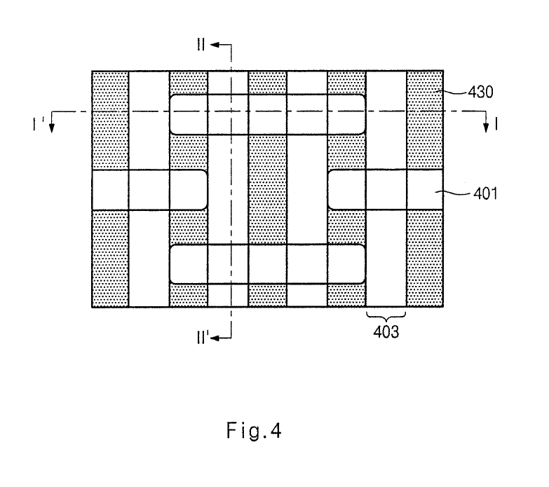

FIG. 4 is a simplified layout of a semiconductor device according to one embodiment of the present invention. The semiconductor device includes an active region 401 and a gate region 403. A device isolation structure 430 defines the active region 401.

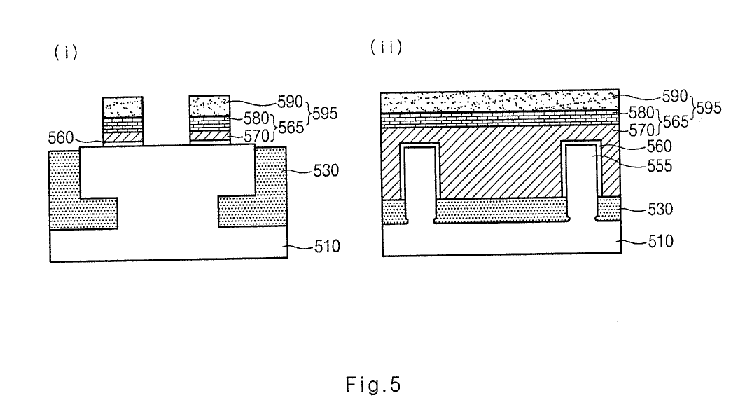

FIG. 5 is a simplified cross-sectional view of a semiconductor device formed from a semiconductor substrate 510 according to one embodiment of the present invention, wherein FIG. 5(i) is a cross-sectional view taken along a latitudinal direction in accordance with the line I-I′ of FIG. 4 and FIG. 5(ii) is a cross-sectional view taken along a longitudinal direction in accordance with the line II-II′ of FIG. 4. A device isolation structure 530 defines an active region 401 shown in FIG. 4 having a recess region at a lower part of sidewalls of the active region 401. The recess region includes a portion of a storage node junction region 607 shown in FIG. 6 and a channel region 609 adjacent to the storage node junction region 607. A fin channel region 555 is protruded over the device isolation structure 530 in a longitudinal direction of a gate region 403 shown in FIG. 4. A gate insulating film 560 is formed over the active region 401 shown in FIG. 4 including the protruded fin channel region 555. A gate structure 595 is formed over the gate insulating film 560 of the gate region 403 shown in FIG. 4 to fill up the protruded fin channel region 555. Here, the gate structure 595 includes a stacked structure of a gate electrode 565 and a gate hard mask layer pattern 590. The gate electrode 565 includes a stacked structure of a lower gate electrode 570 and an upper gate electrode 580. In one embodiment of the present invention, the gate insulating film 560 is formed using O₂, H₂O, O₃, and combinations thereof with its thickness ranging from about 1 nm to about 10 nm. In addition, the lower gate electrode 570 includes a polysilicon doped with impurities such as P or B. The upper gate electrode 580 includes one selected from the group consisting of a titanium (Ti) layer, a titanium nitride (TiN) film, a tungsten (W) layer, an aluminum (Al) layer, a copper (Cu) layer, a tungsten silicide (WSiₓ) layer and combinations thereof. In another embodiment, the gate insulating film 560 is selected from the group consisting of a silicon nitride film, a hafnium oxide film, an aluminum oxide film, a zirconium oxide film, a silicon nitride film and combinations thereof with its thickness ranging from about 1 nm to about 20 nm.

FIG. 6 is a perspective, cross-sectional view of a semiconductor device according to one embodiment of the present invention. It shows a fin channel region including the active region 401 shown in FIG. 4 having a recess region at a lower part of sidewalls of the active region. Here, the recess region includes a portion of a storage node junction region 607 and a channel region 609 adjacent to the storage node junction region 607.

Referring to FIG. 6, depth D is a depth from the semiconductor substrate 610 under the storage node junction region 607 to the bottom of the fin channel region. The distance D is at least 0 (i.e. 0≦D<H) in order to prevent a storage node from directly being connected with body of the semiconductor substrate 610. Distance X is a distance of the removed semiconductor substrate 610 in a longitudinal direction of the active region 401 shown in FIG. 4. The distance X includes a portion of the storage node junction region 607 and the channel region 609 adjacent to the storage node junction region 607. In addition, the distance X can extend from the storage node junction region 607 to the neighboring channel region 609. Depth T is a depth of the semiconductor substrate 610 of the storage node junction region 607. In fact, the depth T is the same as a depth of the fin channel region 555 shown in FIG. 5. Accordingly, the depth T can be adjusted considering size of channel area or amount of the operating current. Depth H is a depth of the recessed semiconductor substrate 610 under the active region 401 shown in FIG. 4. The depth H is at least greater than the depth D.

In one embodiment of the present invention, the storage node is not directly connected with the body of the semiconductor substrate 610 to prevent gate-induced drain leakage (“GIDL”) current, which occurs due to the storage node and the gate voltage, from flowing into the body of the semiconductor substrate 610. As a result, reducing the stored charges in the storage node can be prevented. In addition, a gate channel is formed at the fin channel region 555 shown in FIG. 5 to obtain a sufficient channel area. Accordingly, it is expected to improve the short channel effect (“SCE”) of the device.

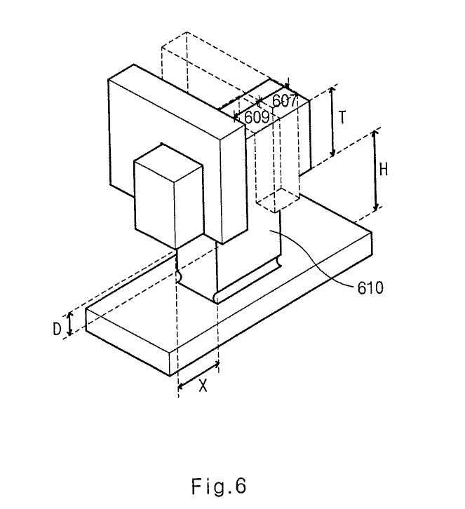

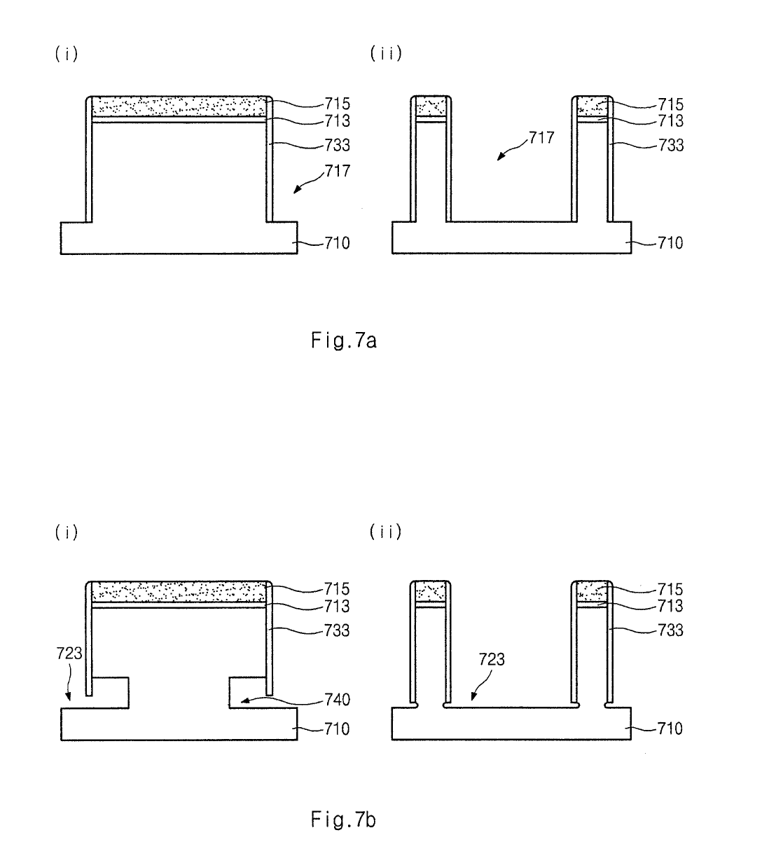

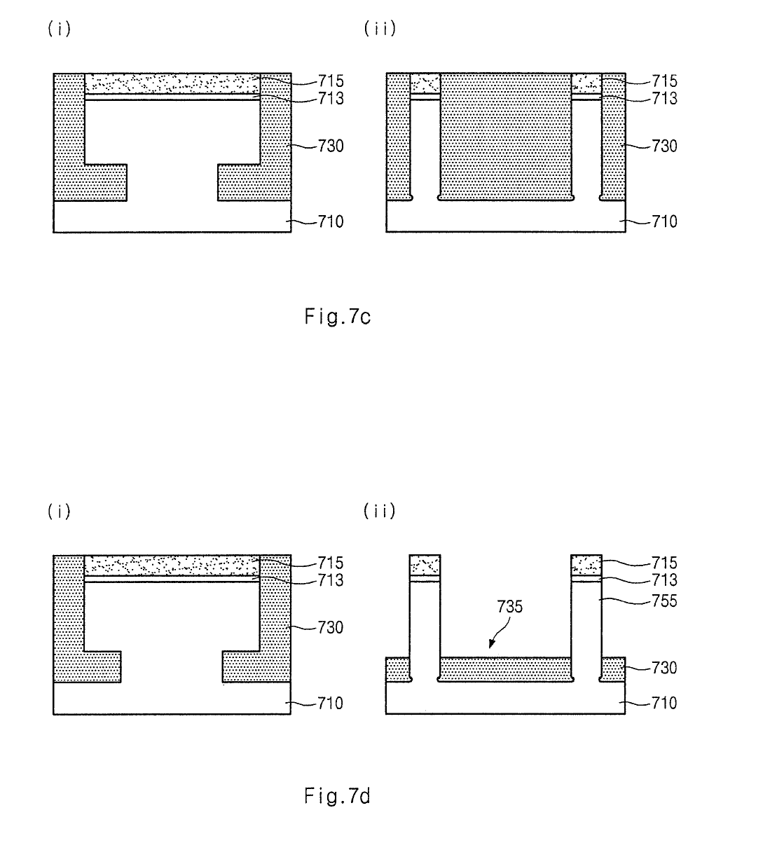

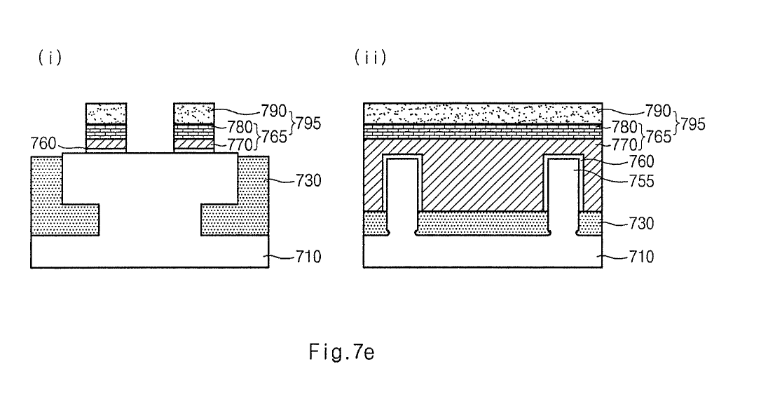

FIGS. 7a through 7e are simplified cross-sectional views illustrating a method for fabricating a semiconductor device according to one embodiment of the present invention, wherein FIGS. 7a(i) through 7e(i) are cross-sectional views taken along a latitudinal direction in accordance with the line I-I′ of FIG. 4 and FIGS. 7a(ii) through 7e(ii) are cross-sectional views taken along a longitudinal direction in accordance with the line II-II′ of FIG. 4. A pad oxide film 713 and a pad nitride film 715 are formed over a semiconductor substrate 710. The pad nitride film 715, the pad oxide film 713, and the semiconductor substrate 710 are etched using a device isolation mask (not shown) as an etching mask to form a first trench 717 defining an active region 401 shown in FIG. 4. A first insulating film (not shown) is formed over an entire surface of the resultant (i.e. over the trench 717 and the semiconductor substrate 710). The first insulating film is etched to form first spacers 733 at sidewalls of the first trench 717. In one embodiment of the present invention, the first insulating film is selected from the group consisting of a silicon nitride film, a silicon oxide film, a silicon film and combinations thereof by a chemical vapor deposition (“CVD”) method or an atomic layer deposition (“ALD”) method. A thickness of the first insulating film ranges from about 1 nm to 100 nm. In addition, the etching process for the first insulating film is performed by a dry etching method. In particular, the etching process for forming the first spacer 733 is performed by a plasma etching method using one selected from the group consisting of CₓF_{y}H_{z}, O₂, HCl, Ar, He and combinations thereof.

Referring to FIG. 7b, the semiconductor substrate 710 exposed under the first trench 717 is etched to form a second trench 723 including an under-cut space 740 where the semiconductor substrate 710 under a predetermined region is removed. In one embodiment of the present invention, the etching process for forming the second trench 723 is performed by exposing the semiconductor substrate 710 exposed under the first trench 717 at an atmosphere of a mixture gas of HCl and H₂ and at a temperature ranging from about 500° C. to about 1,000° C. In addition, the predetermined region includes a portion of the storage node junction region 607 shown in FIG. 6 and the channel region 609 adjacent to the storage node junction region 607. Here, the under-cut space 740 is formed due to different etch rates in accordance with silicon crystal planes during the removing process for the semiconductor substrate 710. In particular, since the etch rate of the semiconductor substrate 710 in a longitudinal direction of the active region 401 shown in FIG. 4 is relatively faster than that of any crystal plane, the under-cut space 740 where the semiconductor substrate 710 under the predetermined region is removed can be formed.

Referring to FIG. 7c, the first spacer 733 is removed. An insulating film for device isolation (not shown) is formed to fill up the second trench 723 including the under-cut space 740. The insulating film for device isolation is polished until the pad nitride film 715 is exposed to form a device isolation structure 730. In one embodiment of the present invention, without the removing process for the first spacer 733, the insulating film for device isolation can be formed to fill up the second trench 723 including the under-cut space 740. In addition, a thermal oxide film (not shown) can further be formed at the interface of the device isolation structure 730 and the second trench 723 including the under-cut space 740. Here, the semiconductor substrate 710 is exposed at one selected from the group consisting of H₂O, O₂, H₂, O₃ and combinations thereof and at a temperature ranging from about 200° C. to 1,000° C. to form the thermal oxide film. In another embodiment, the insulating film for device isolation is formed of a silicon oxide film by a high density plasma (“HDP”) method or a CVD method. In addition, the polishing process for forming the device isolation structure 730 is performed by a chemical mechanical planarization (“CMP”) method.

Referring to FIG. 7d, a predetermined thickness of the device isolation structure 730 is etched using a recess gate mask (not shown) defining the gate region 403 shown in FIG. 4 to form a recess region 735 exposing upper sidewalls of the active region 401. Here, the recess region 735 defines a fin channel region 755 protruded over the device isolation structure 730. In one embodiment of the present invention, the pad nitride film 715, the pad oxide film 713, and a predetermined thickness of the device isolation structure 730 may be etched using the recess gate mask defining the gate region 403 shown in FIG. 4 to form the recess region 735 exposing the upper sidewalls of the active region 401 in a longitudinal direction of the gate region 403. In addition, the etching process for the device isolation structure 730 is performed by a dry etching method.

Referring to FIG. 7e, the pad nitride film 715 and the pad oxide film 713 shown in FIG. 7d are removed to expose the semiconductor substrate 710 including the fin channel region 755. A gate insulating film 760 is formed over the exposed semiconductor substrate 710. A lower gate conductive layer (not shown) is formed to fill up the recess region 735 including the fin channel region 755. An upper gate conductive layer (not shown) and a gate hard mask layer (not shown) are formed over the lower gate conductive layer. The gate hard mask layer, the upper gate conductive layer, the lower gate conductive layer, and the gate insulating film 760 are patterned using a gate mask (not shown) to form a gate structure 795 including a stacked structure of a gate electrode 765 and a gate hard mask layer pattern 790. In one embodiment of the present invention, a process for cleaning a surface of the exposed semiconductor substrate 710 by using a solution including HF may be further performed before the process for forming the gate insulating film 760. In addition, the removing process for the pad nitride film 715 and the pad oxide film 713 is performed by a wet etching method using H₃PO₄. The gate insulating film 760 is also formed using one selected from the group consisting of O₂, H₂O, O₃ and combinations thereof with its thickness ranging from about 1 nm to about 10 nm. In another embodiment, the lower gate conductive layer is formed of a polysilicon layer doped with impurities including P or B. Here, the doped polysilicon layer may be formed by implanting impurity ions into an undoped polysilicon layer or by using a silicon source gas and an impurity source gas including P or B. In addition, the upper gate conductive layer is selected from the group consisting of a titanium (Ti) layer, a titanium nitride (TiN) film, a tungsten (W) layer, an aluminum (Al) layer, a copper (Cu) layer, a tungsten silicide (WSiₓ) layer and combinations thereof. In other embodiment, the gate insulating film 760 is selected from the group consisting of a silicon oxide film, a hafnium oxide film, an aluminum oxide film, a zirconium oxide film, a silicon nitride film and combinations thereof with its thickness ranging from about 1 nm to about 20 nm. On the other hand, in order to increase an effective channel length of the device, a silicon layer (not shown) is grown using the semiconductor substrate 710 exposed at both sides of the gate structure 795 as a seed layer with its thickness ranging from about 200 Å to about 1,000 Å. The grown silicon layer is implanted with impurity ions to form source/drain regions. Therefore, there is a height difference between the channel region and the source/drain regions.

In addition, subsequent processes such as a process for forming gate spacers, a process for forming a landing plug, a process for forming a bit line contact and a bit line, a process for forming a capacitor, and a process for forming an interconnect may be performed.

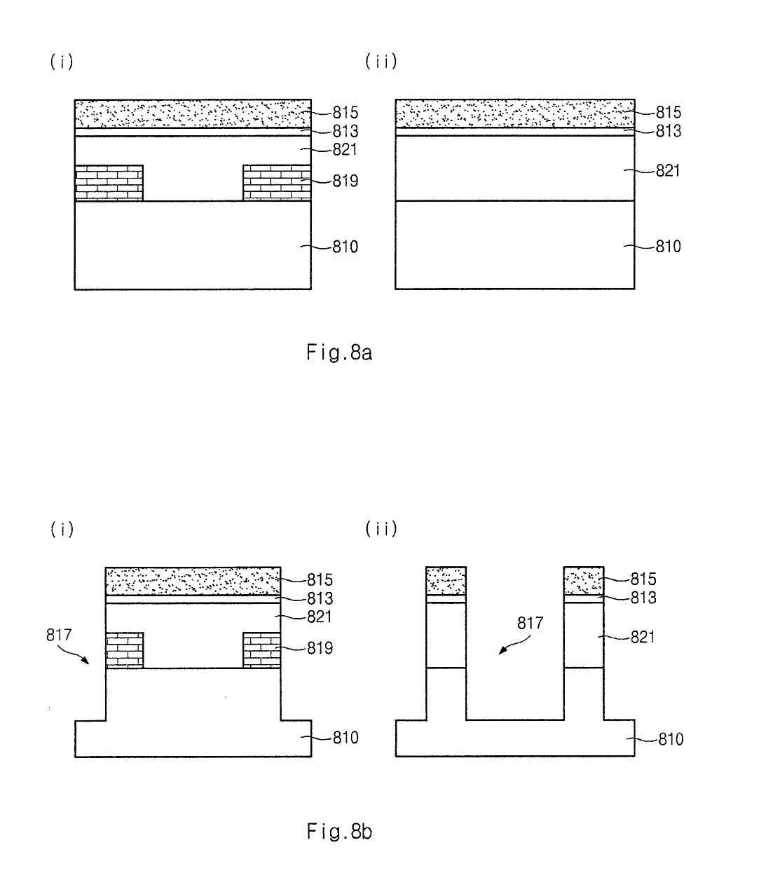

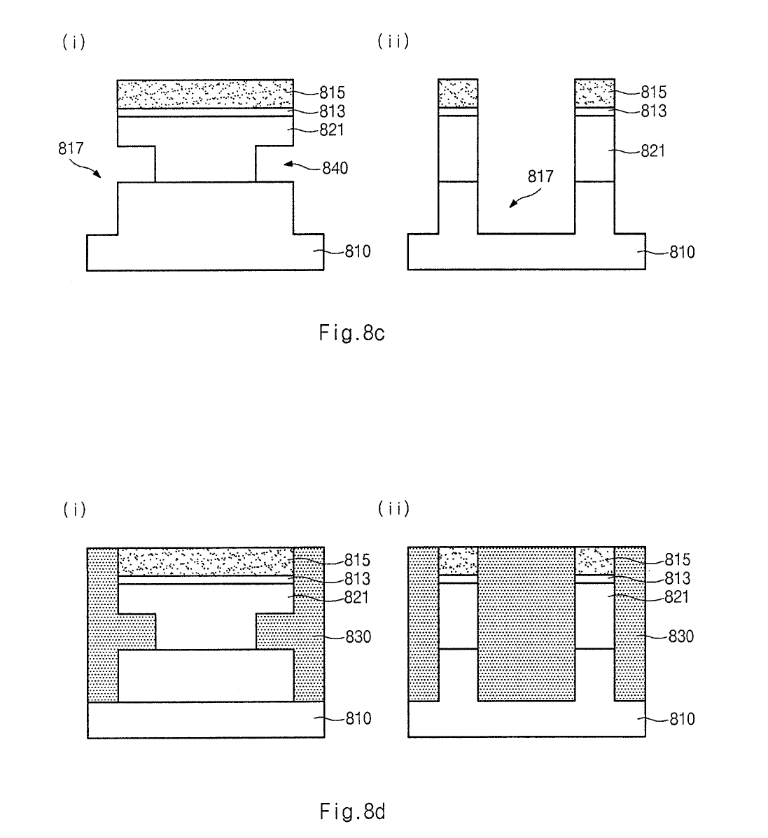

FIGS. 8a through 8d are simplified cross-sectional views illustrating a method for fabricating a semiconductor device according to another embodiment of the present invention. In the method, a recess region where a semiconductor substrate at a lower part of sidewalls of an active region is to be removed in a subsequent process is formed of a SiGe layer in order to easily remove the semiconductor substrate corresponding to the recess region. Here, FIG. 8a(i) through 8d(i) are cross-sectional views taken along a latitudinal direction in accordance with the line I-I′ of FIG. 4, and FIGS. 8a(ii) through 8d(ii) are cross-sectional views taken along a longitudinal direction in accordance with the lines II-II′ of FIG. 4.

Referring to FIG. 8a, a cleaning process is performed on a surface of the semiconductor substrate 810. A SiGe layer 819 is formed over the semiconductor substrate 810. The SiGe layer 819 is selectively removed using a mask (not shown) covering the recess region to expose the semiconductor substrate 810. A silicon layer 821 is formed using the exposed semiconductor substrate 810 as a seed layer to fill up the SiGe layer 819. A pad oxide film 813 and a pad nitride film 815 are formed over the silicon layer 821. In one embodiment of the present invention, the removing process for the SiGe layer 819 is performed by a dry etching method. In addition, the recess region includes a portion of the storage node junction region 607 shown in FIG. 6 and the channel region 609 adjacent to the storage node junction region 607 in a longitudinal direction 401 shown in FIG. 4.

Referring to FIGS. 8b and 8c, the pad nitride film 815, the pad oxide film 813, the silicon layer 821, and the semiconductor substrate 810 are etched using a device isolation mask (not shown) to form a trench defining the active region 401 shown in FIG. 4. At this time, the SiGe layer 819 is exposed at the sidewalls of the trench 817. The SiGe layer exposed at the sidewalls of the trench 817 is etched to form an under-cut space 840. In one embodiment of the present invention, since an etch rate of the SiGe layer 819 is faster than that of the semiconductor substrate 810, the under-cut space 840 can be formed. In addition, a ratio of the etch rate of the SiGe layer 819 to that of the semiconductor substrate 810 is at least 10.

Referring to FIG. 8d, an insulating film for device isolation (not shown) is formed to fill up the trench 817 including the under-cut space 840. The insulating film for device isolation is polished until the pad nitride film 815 is exposed to form a device isolation structure 830. In one embodiment of the present invention, a thermal oxide film (not shown) can be further formed at the interface of the device isolation structure 830 and the trench 817 including the under-cut space 840. Here, the semiconductor substrate 810 is exposed at one selected from the group consisting of H₂O, O₂, H₂, O₃, and combinations thereof and at a temperature ranging from about 200° C. to about 1,000° C. to from the thermal oxide film. In addition, subsequent processes may be performed by the method for fabricating a semiconductor device shown in FIGS. 7d through 7e.

As described above, the semiconductor device having the active region having a recess region at a lower part of the sidewalls of the active region and the fin channel region protruded over the device isolation structure and the semiconductor device fabricated by the method described above can obtain relatively large driving current. In addition, the semiconductor substrate under the storage node is removed to prevent the storage node from being directly connected with the body of the semiconductor substrate, thereby structurally reducing the leakage current flowing from the storage node to the body. Accordingly, there is the substantial improvement for the refresh characteristic of the device. Since the semiconductor device has the fin channel region, it can be also easily applicable to the shrunk semiconductor device according to the design rule. Accordingly, the short channel effect of the device can be improved. The lowering of threshold voltage due to drain voltage, body effect, and gate On/Off characteristics can be also improved. According to the present invention, the semiconductor device has extendibility capable of securing substantial channel area of the device despite shrinkage of its design rules.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for fabricating a semiconductor device, the method comprising:
forming a device isolation structure in a semiconductor substrate to form an active region having a recess region at a lower part of sidewalls thereof;
etching the device isolation structure by using a recess gate mask defining a gate region as an etching mask to form a fin channel region protruded over the device isolation structure;
forming a gate insulating film over the exposed semiconductor substrate including the protruded fin channel region; and
forming a gate structure including a stacked structure of a gate hard mask layer pattern and a gate electrode that covers the protruded fin channel region over the gate insulating film corresponding to the gate region,
wherein the forming-a-device-isolation-structure step includes:
forming a SiGe layer over the semiconductor substrate;
removing a predetermined region of the SiGe layer to expose the semiconductor substrate;
growing a silicon layer by using the exposed semiconductor substrate as a seed layer to fill up the SiGe layer;
forming a pad oxide film and a pad nitride film over the silicon layer;
etching the pad nitride film, the pad oxide film, the silicon layer, the SiGe layer, and the semiconductor substrate using a device isolation mask to form a trench defining the active region, wherein the SiGe layer is exposed at sidewalls of the trench;
removing the SiGe layer exposed at the sidewalls of the trench to form the under-cut space under the active region; and
forming the device isolation structure filling the trench including the under-cut space.

2. The method according to claim 1, wherein the removing process for the SiGe layer is performed by a dry etching method.

3. The method according to claim 1, wherein an etching rate of the SiGe layer is at least tenfold of that of the semiconductor substrate.

4. A method for fabricating a semiconductor device, the method comprising:
forming a device isolation structure in a semiconductor substrate to form an active region having a recess region at a lower part of sidewalls thereof;
etching the device isolation structure by using a recess gate mask defining a gate region as an etching mask to form a fin channel region protruded over the device isolation structure;
forming a gate insulating film over the exposed semiconductor substrate including the protruded fin channel region;
forming a gate structure including a stacked structure of a gate hard mask layer pattern and a gate electrode that covers the protruded fin channel region over the gate insulating film corresponding to the gate region;
forming a silicon layer by using the semiconductor substrate at both sides of the gate structure as a seed layer; and
implanting impurity ions into the silicon layer to form source/drain region.

5. The method according to claim 4, wherein a thickness of the silicon layer ranges from about 200 Å to about 1,000 Å.

6. The method according to claim 4, wherein the recess region includes a portion of a storage node region and a channel region adjacent thereto in a longitudinal direction of the active region.

7. The method according to claim 4, further comprising a thermal oxide film at the interface of the semiconductor substrate and the device isolation structure.

8. The method according to claim 7, wherein the thermal oxide film is formed by using one selected from the group consisting of H₂O, O₂, H₂, O₃ and combinations thereof at a temperature ranging from about 200° C. to about 1,000° C.

9. The method according to claim 4, wherein the gate insulating film is formed by using one selected from the group consisting of O₂, H₂O, O₃ and combinations thereof with a thickness ranging from about 1 nm to about 10 nm.

10. The method according to claim 4, wherein the gate insulating film is selected from the group consisting of a silicon oxide film, a hafnium oxide film, an aluminum oxide film, a zirconium oxide film, a silicon nitride film and combinations thereof with a thickness ranging from about 1 nm to about 20 nm.

11. The method according to claim 4, wherein the gate electrode includes a stacked structure of a lower gate electrode and an upper gate electrode, wherein the lower gate electrode is formed of a polysilicon layer doped with impurity ions including P or B, and the upper gate electrode comprises one selected from the group consisting of a titanium (Ti) layer, a titanium nitride (TiN) layer, a tungsten (W) layer, an aluminum (Al) layer, a copper (Cu) layer, a tungsten silicide (WSiₓ) layer and combinations thereof.

12. A method for fabricating a semiconductor device, the method comprising:
forming a device isolation structure in a semiconductor substrate to form an active region having a recess region at a lower part of sidewalls thereof by forming a SiGe layer over the semiconductor substrate and removing the SiGe layer;
etching the device isolation structure by using a recess gate mask defining a gate region as an etching mask to form a fin channel region protruded over the device isolation structure;
forming a gate insulating film over the exposed semiconductor substrate including the protruded fin channel region; and
forming a gate structure including a stacked structure of a gate hard mask layer pattern and a gate electrode that covers the protruded fin channel region over the gate insulating film corresponding to the gate region.

13. The method according to claim 12, wherein the removing process for the SiGe layer is performed by a dry etching method.

14. The method according to claim 12, wherein an etching rate of the SiGe layer is at least tenfold of that of the semiconductor substrate.

15. The method according to claim 12, wherein the recess region includes a portion of a storage node region and a channel region adjacent thereto in a longitudinal direction of the active region.

16. The method according to claim 12, further comprising a thermal oxide film at the interface of the semiconductor substrate and the device isolation structure.

17. The method according to claim 16, wherein the thermal oxide film is formed by using one selected from the group consisting of H₂O, O₂, H₂, O₃ and combinations thereof at a temperature ranging from about 200° C. to about 1,000° C.

18. The method according to claim 12, wherein the gate insulating film is formed by using one selected from the group consisting of O₂, H₂O, O₃ and combinations thereof with a thickness ranging from about 1 nm to about 10 nm.

19. The method according to claim 12, wherein the gate insulating film is selected from the group consisting of a silicon oxide film, a hafnium oxide film, an aluminum oxide film, a zirconium oxide film, a silicon nitride film and combinations thereof with a thickness ranging from about 1 nm to about 20 nm.

20. The method according to claim 12, wherein the gate electrode includes a stacked structure of a lower gate electrode and an upper gate electrode, wherein the lower gate electrode is formed of a polysilicon layer doped with impurity ions including P or B, and the upper gate electrode comprises one selected from the group consisting of a titanium (Ti) layer, a titanium nitride (TiN) layer, a tungsten (W) layer, an aluminum (Al) layer, a copper (Cu) layer, a tungsten silicide (WSiₓ) layer and combinations thereof.
